(19) United States
(12) Patent Application Publication
(10) Pub. No.: US 2026/0223303 A1
(43) Pub. Date: Jul. 30, 2026

(54) Server System Rack Ejection System

(71) Applicant: Dell Products L.P., Round Rock, TX (US)

(72) Inventors: Derek Siems, Austin, TX (US); David L. Roper, Austin, TX (US)

(21) Appl. No.: 19/037,995

(22) Filed: Jan. 27, 2025

(51) Int. Cl. H05K 5/02; G08C 17/02

(52) U.S. Cl. CPC H05K 5/0221; G08C 17/02

(57) ABSTRACT

A rack ejection system of a server type information handling system. The rack ejection system of a server type information handling system includes a cam lever, the cam lever including a cam lever lock mechanism, the cam lock mechanism being configured to engage the cam lever with a chassis of the information handling system; and, an ejection device mounted on the cam lever, the ejection system being configured to manipulate the cam lever lock mechanism of the cam lever, manipulating the cam lever lock mechanism disengaging the cam lever from the chassis of the information handling system.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server type information handling system with a rack ejection system.

In one embodiment, the invention relates to a rack ejection system of a server type information handling system, comprising: a cam lever, the cam lever including a cam lever lock mechanism, the cam lock mechanism being configured to engage the cam lever with a chassis of the information handling system; and, an ejection device mounted on the cam lever, the ejection system being configured to manipulate the cam lever lock mechanism of the cam lever, manipulating the cam lever lock mechanism disengaging the cam lever from the chassis of the information handling system.

In another embodiment, the invention relates to server type information handling system comprising: an information handling system chassis; and, rack ejection system coupled to the information handling system chassis, the rack ejection system comprising: a cam lever, the cam lever including a cam lever lock mechanism, the cam lock mechanism being configured to engage the cam lever with the information handling system chassis; and, an ejection device mounted on the cam lever, the ejection system being configured to manipulate the cam lever lock mechanism of the cam lever, manipulating the cam lever lock mechanism disengaging the cam lever from the information handling system chassis.

In another embodiment, the invention relates to a system comprising: a server rack; and, an information handling system mounted to the server rack, the information handing system comprising: an information handling system chassis; and, rack ejection system coupled to the information handling system chassis, the rack ejection system comprising: a cam lever, the cam lever including a cam lever lock mechanism, the cam lock mechanism being configured to engage the cam lever with the information handling system chassis; and, an ejection device mounted on the cam lever, the ejection system being configured to manipulate the cam lever lock mechanism of the cam lever, manipulating the cam lever lock mechanism disengaging the cam lever from the information handling system chassis.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIG. 4 shows a generalized front perspective view of a server type information handling system mounted within a server rack.

FIG. 5 shows a front perspective view of a server type information handling system with a server rack ejection system.

FIG. 6 shows a cut away perspective view of a server rack ejection system.

FIG. 7 shows a front perspective view of a server rack ejection component in a disengaged orientation.

### DETAILED DESCRIPTION

Various aspects of the disclosure include an appreciation that with server type information handling systems, high power components such as processors, graphics processing units, etc. can have very demanding cooling needs. Various aspects of the present disclosure include an appreciation that it is known to design information handling systems with liquid cooling capabilities to address these cooling needs.

Various aspects of the present disclosure include an appreciation that known information handling system designs often conform to various standards. Various aspects of the present disclosure include an appreciation that the Open Compute Project Open Rack Version 3 (ORv3) standard is one such standard. Various aspects of the present disclosure include an appreciation that the Orv3 standard defines various aspects relating to a server type information handing system, information handling system chassis and server rack ecosystem. Various aspects of the present disclosure include an appreciation that this ecosystem can incorporate a rack-length rear power rail, referred to as Bus Bar, and a rear mounted liquid cooling manifold with an inlet and outlet quick disconnect connector for every server slot.

Various aspects of the present disclosure include an appreciation that server information handling systems connect to the power rail and the liquid cooling manifold when inserted into the rack. Various aspects of the present disclosure include an appreciation that disconnecting the server information handling system from the rack releases the server information handling system from power and liquid cooling seamlessly. Various aspects of the present disclosure include an appreciation that with known designs, disconnecting the server information handling system from the rack is a manual process requiring human intervention which cannot be initiated remotely. Various aspects of the present disclosure include an appreciation that because liquid cooling leak events can quickly escalate into catastrophic loss events, it is desirable that measures can be taken to mitigate risk of leaks continuing once detected.

Various aspects of the present disclosure include an appreciation that server information handling systems which conform to the Orv3 standard are often prone to user error in the event of a fluid leak emergency. Various aspects of the present disclosure include an appreciation that server information handling systems can be difficult to address a leak event for remotely located server rooms. For example, a user simply powers off a leaking server from the front button of the server information handling system does not stop the flow of coolant through the server information handling system. Without the flow of coolant stopped, the information handling system can continue to leak and damage the server information handling system and potentially surrounding equipment. Additionally, if a user simply shuts off flow from a coolant distribution unit (CDU) via a valve or CDU shutdown, etc. without first powering off the server information handling system, temperatures can quickly increase and potentially damage the server information handling system from overheating.

Various aspects of the present disclosure include an appreciation that it would be desirable to eject and/or disconnect the server information handling system from the server rack, thereby disconnecting the liquid quick and removing power from the bus bar in the event of a server leak being detected. Various aspects of the present disclosure include an appreciation that it would be desirable to enable this ejection, disconnection to be performed remotely.

A system and method for providing server information handling system with a rack ejection system. In certain embodiments, the rack ejection system includes a rack ejection device. In certain embodiments, the rack ejection system includes a pair of rack ejection devices. In certain embodiments, the rack ejection system includes a retrofittable rack ejection device.

In certain embodiments, the rack ejection system includes a cam lever pivotally mounted to a front of a chassis of the server information handling system. In certain embodiments, the rack ejection device is attached to the cam lever. In certain embodiments, the rack ejection system includes a pair of cam levers pivotally mounted to the front of the chassis. In certain embodiments, a rack ejection device is attached to each of the pair of cam levers. In certain embodiments, the server information handling system conforms to the ORv3 server standard. In certain embodiments, the cam levers conform to the Orv3 server standard.

In certain embodiments, the rack ejection devices generates a mechanical pinching action. In certain embodiments, the mechanical pinching action triggers the lock release of the cam lever. In certain embodiments, by triggering the lock release of the cam lever, generates a spring force which causes the pressurized coolant quick disconnects to naturally push the server information handling system forward and clear of the liquid and power connections thereby rending the server safely disabled. In certain embodiments, this forward movement is relatively small (e.g., about an inch or two forward).

In certain embodiments, the rack ejection device includes a motor, a gear assembly, a finger component, or a combination thereof. In certain embodiments, the motor and gear assembly generate a high torque force that is applied to the finger component. In certain embodiments, the motor and gear assembly drive the finger component. In certain embodiments, the finger component trips the release mechanism of a cam handle of the cam. In certain embodiments, the rack ejection device may be controlled remotely.

Such a rack ejection system advantageously provides a server-level power and liquid cooling disconnect system. In certain embodiments, the rack ejection system includes a pair of for server information handling systems conforming to the Orv3 server standard. Such a rack ejection system advantageously provides an automated remote system which prevents damage to server information handling system equipment.

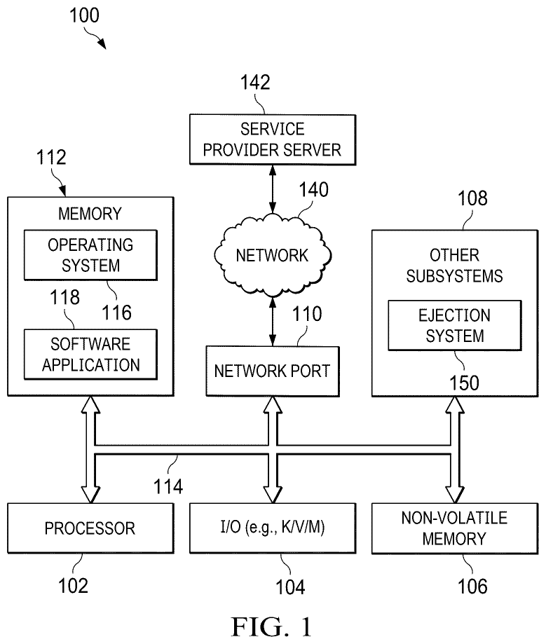

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 includes an ejection system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the ejection system 150 includes a rack ejection system. In certain embodiments, the rack ejection system includes a rack ejection device. In certain embodiments, the rack ejection system includes a pair of rack ejection devices. In certain embodiments, the rack ejection system includes a retrofittable rack ejection device.

In certain embodiments, the rack ejection system includes a cam lever pivotally mounted to a front of a chassis of the server information handling system. In certain embodiments, the rack ejection device is attached to the cam lever. In certain embodiments, the rack ejection system includes a pair of cam levers pivotally mounted to the front of the chassis. In certain embodiments, a rack ejection device is attached to each of the pair of cam levers. In certain embodiments, the server information handling system conforms to the ORv3 server standard. In certain embodiments, the cam levers conform to the Orv3 server standard.

In certain embodiments, the rack ejection device generates a mechanical pinching action. In certain embodiments, the mechanical pinching action triggers the lock release of the cam lever. In certain embodiments, by triggering the lock release of the cam lever, generates a spring force which causes the pressurized coolant quick disconnects to naturally push the server information handling system forward and clear of the liquid and power connections thereby rending the server safely disabled. In certain embodiments, this forward movement is relatively small (e.g., about an inch or two forward).

In certain embodiments, the rack ejection device includes a motor, a gear assembly, a finger component, or a combination thereof. In certain embodiments, the motor and gear assembly generate a high torque force that is applied to the finger component. In certain embodiments, the motor and gear assembly drive the finger component. In certain embodiments, the finger component trips the release mechanism of a cam handle of the cam. In certain embodiments, the rack ejection device may be controlled remotely.

Such a rack ejection system advantageously provides a server-level power and liquid cooling disconnect system. In certain embodiments, the rack ejection system includes a pair of for server information handling systems conforming to the Orv3 server standard. Such a rack ejection system advantageously provides an automated remote system which prevents damage to server information handling system equipment.

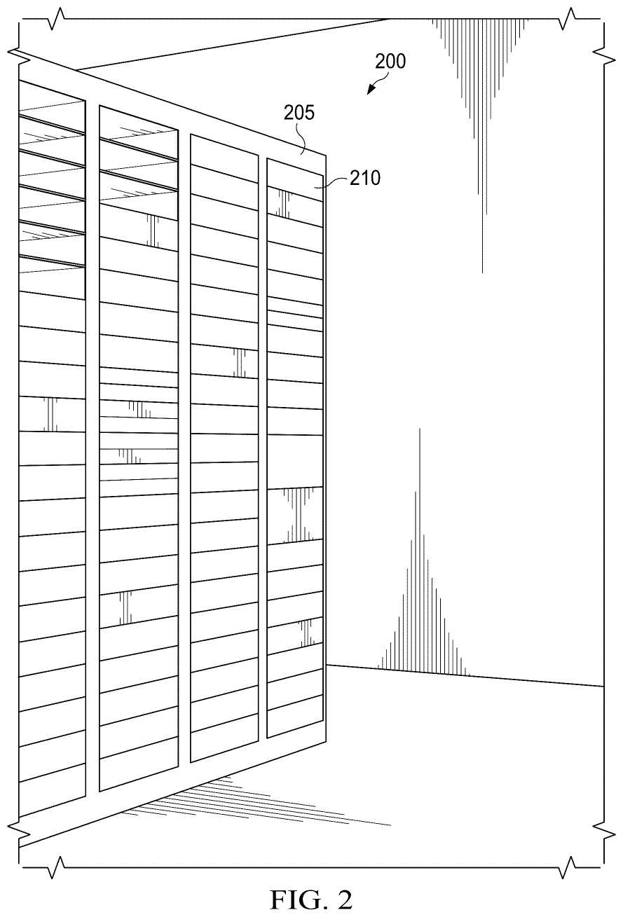

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks are arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit and a 4U rack unit. In general, a 1U rack unit is substantially (i.e., +/−20%) 1.75″ high, a 2U rack unit is substantially (i.e., +/−20%) 3.5″ high and a 4U rack height is substantially (i.e., +/−20%) 7.0″ high.

In certain embodiments, some or all of the information handling systems 210 are configured as hermetically sealed liquid cooled information handling systems. In certain embodiments, the hermetically sealed liquid cooled information handling systems correspond to systems having high powered heat producing components. In certain embodiments, other information handling systems 210 are configured as air cooled information handling systems. In certain embodiments, the air cooled information handling systems correspond to systems that do not require liquid cooling to function properly.

n certain embodiments, the rack includes a coolant distribution unit. In certain embodiments, the liquid cooled information handling systems are thermally coupled with the cooling distribution unit. In certain embodiments, the coolant distribution unit provides a closed loop via which the coolant is provided to and removed from the liquid cooled information handling systems. In certain embodiments, the coolant distribution unit can simultaneously facilitate cooling of multiple information handling systems.

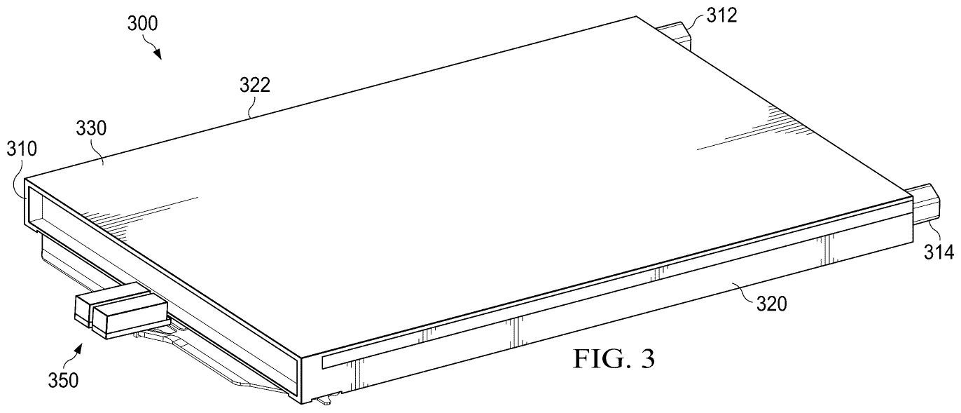

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the blade type information handing system 300 includes a bay via which components may be mounted to the blade type information handling system.

In certain embodiments, the information handling system 300 is configured for internal immersion cooling. As used herein, immersion cooling broadly refers to a technique used for cooling in which heat producing components of the information handling system are submerged in a thermally conductive but electrically insulating liquid coolant. With immersion cooling, the heat producing components are contained within a liquid tight chassis. With immersion cooling, heat produced by the heat producing components is removed from the information handling system by placing the coolant in direct thermal contact with hot components. The liquid which is heated from the contact with the hot components is circulated through heat exchangers. Immersion cooling is highly effective because liquid coolants absorb heat from the components of the information handling system as the liquid is circulated through the system.

In certain embodiments, the information handling system 300 is configured as a hermetically sealed enclosed chassis. The enclosed chassis includes cooling liquid inlet connector 312 and a cooling liquid outlet connector 314 to interface cooling liquid with the individual chassis. In certain embodiments, the hermetically sealed enclosed chassis is configured to be mounted within a rack. The connectors are thermally coupled with a closed loop cooling distribution unit which provides a closed loop via which the coolant is provided to and removed from the enclosed chassis. In certain embodiments, cooling of the liquid contained within the closed loop is facilitated by the coolant distribution unit.

In various embodiments, the top panel 330 is part of a chassis liquid cooling liquid distribution component. In certain embodiments, the chassis liquid cooling liquid distribution component is associated with a chassis top panel portion (i.e., a chassis lid portion). In certain embodiments, the chassis top panel portion is configured to hermetically seal the server chassis when installed, thereby maintaining the coolant within the chassis, and to be removable to allow for service of internal server components. In certain embodiments, the chassis top panel portion includes and is integrated with a coolant inlet. In certain embodiments, one or both the walls of the chassis and the top panel portion 330 include sealing components which assist in sealing the top panel portion 330 to the walls of the chassis when the top panel is installed on the chassis. In certain embodiments, the sealing components include gaskets.

In certain embodiments, the coolant inlet is coupled to the cooling liquid inlet connector 312. In certain embodiments, the chassis top panel portion is configured with a liquid distribution chamber which functions as a cavity which distributes the coolant received via the coolant input. In certain embodiments, the chassis top panel portion is configured with a plurality of liquid exit apertures. In certain embodiments, the plurality of liquid exit apertures includes variously shaped exits or lengthened passageways which function as ducts to shape the cooling liquid flow. In certain embodiments, the plurality of liquid exit apertures shape the quantity and path of the cooling liquid flow towards higher powered components of the server type information handling system.

In certain embodiments, the information handing system 300 includes an ejection system 350. In certain embodiments, the ejection system 350 corresponds to ejection system 150. In certain embodiments, the ejection system 350 includes a rack ejection system. In certain embodiments, the rack ejection system includes a rack ejection device. In certain embodiments, the rack ejection system includes a pair of rack ejection devices. In certain embodiments, the rack ejection system includes a retrofittable rack ejection device.

In certain embodiments, the rack ejection system includes a cam lever pivotally mounted to a front of a chassis of the server information handling system. In certain embodiments, the rack ejection device is attached to the cam lever. In certain embodiments, the rack ejection system includes a pair of cam levers pivotally mounted to the front of the chassis. In certain embodiments, a rack ejection device is attached to each of the pair of cam levers. In certain embodiments, the server information handling system conforms to the ORv3 server standard. In certain embodiments, the cam levers conform to the Orv3 server standard.

In certain embodiments, the rack ejection device generates a mechanical pinching action. In certain embodiments, the mechanical pinching action triggers the lock release of the cam lever. In certain embodiments, by triggering the lock release of the cam lever, generates a spring force which causes the pressurized coolant quick disconnects to naturally push the server information handling system forward and clear of the liquid and power connections thereby rending the server safely disabled. In certain embodiments, this forward movement is relatively small (e.g., about an inch or two forward).

In certain embodiments, the rack ejection device includes a motor, a gear assembly, a finger component, or a combination thereof. In certain embodiments, the motor and gear assembly generate a high torque force that is applied to the finger component. In certain embodiments, the motor and gear assembly drive the finger component. In certain embodiments, the finger component trips the release mechanism of a cam handle of the cam. In certain embodiments, the rack ejection device may be controlled remotely.

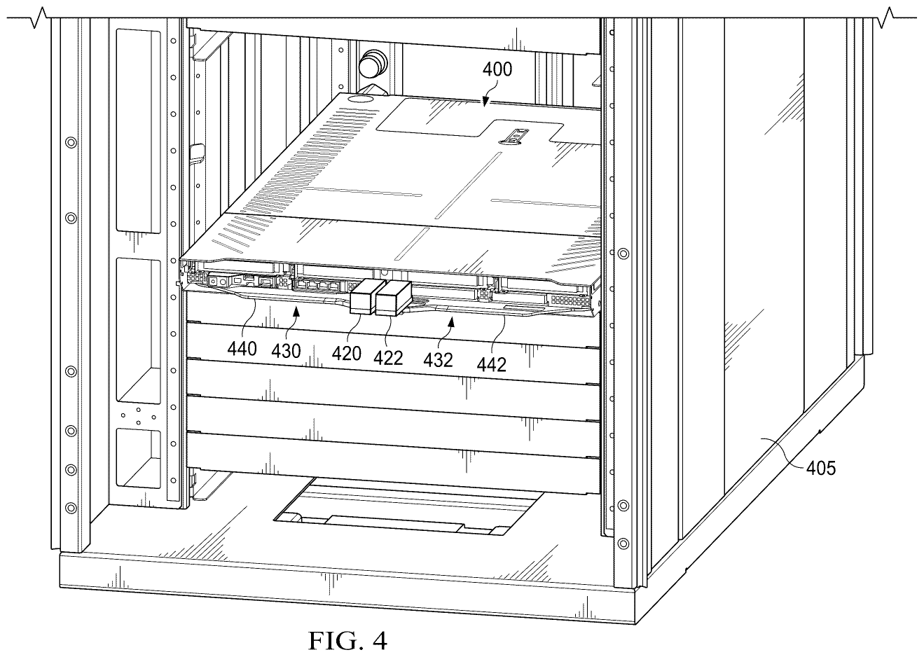

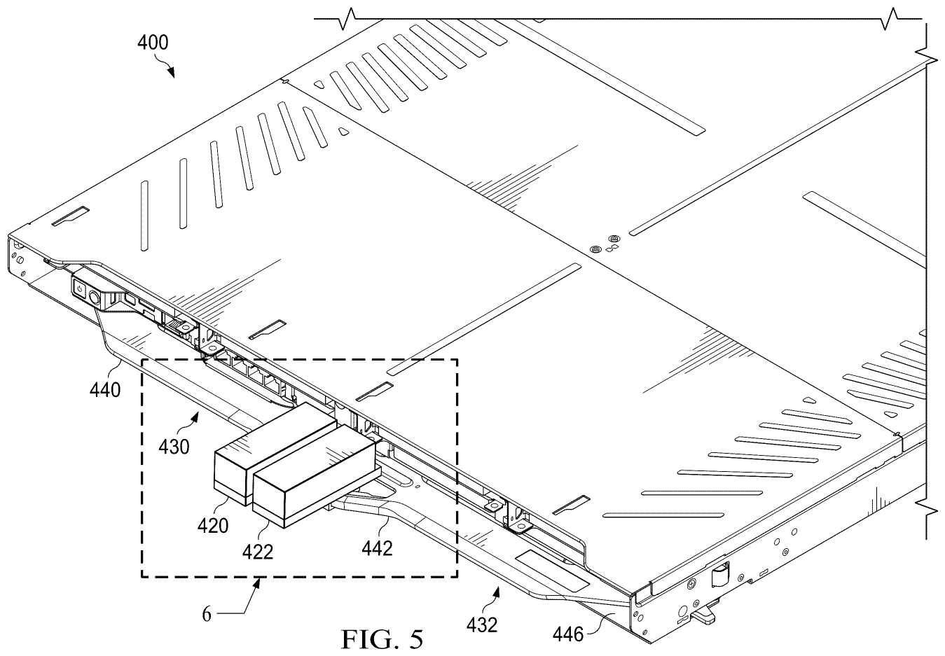

FIG. 4 shows a generalized front perspective view of a server type information handling system 400 mounted within a server rack 405. FIG. 5 shows a front perspective view of a server type information handling system with a server rack ejection system. In certain embodiments, the server type information handling system 400 includes an ejection system 410.

In certain embodiments, the ejection system 410 includes a rack ejection system. In certain embodiments, the rack ejection system includes a rack ejection device 420. In certain embodiments, the rack ejection system includes a pair of rack ejection devices 420, 422. In certain embodiments, the rack ejection system includes a retrofittable rack ejection device. In certain embodiments, the pair of rack ejection devices 420, 422 include a first side rack ejection device and a second side rack ejection device. In certain embodiments, the first side rack ejection device includes a left side rack ejection device. In certain embodiments, the second side rack ejection device includes a right side rack ejection device.

In certain embodiments, the rack ejection system includes a cam lever 430 pivotally mounted to a front of a chassis of the server information handling system 400. In certain embodiments, the rack ejection device 420 is physically mounted to the cam lever 430. In certain embodiments, the rack ejection system includes a pair of cam levers 430, 432 pivotally mounted to the front of the chassis. In certain embodiments, the pair of cam levers 430, 432 include a first side cam lever and a second side cam lever. In certain embodiments, the first side cam lever includes a left side cam lever. In certain embodiments, the second side cam lever includes a right side cam lever.

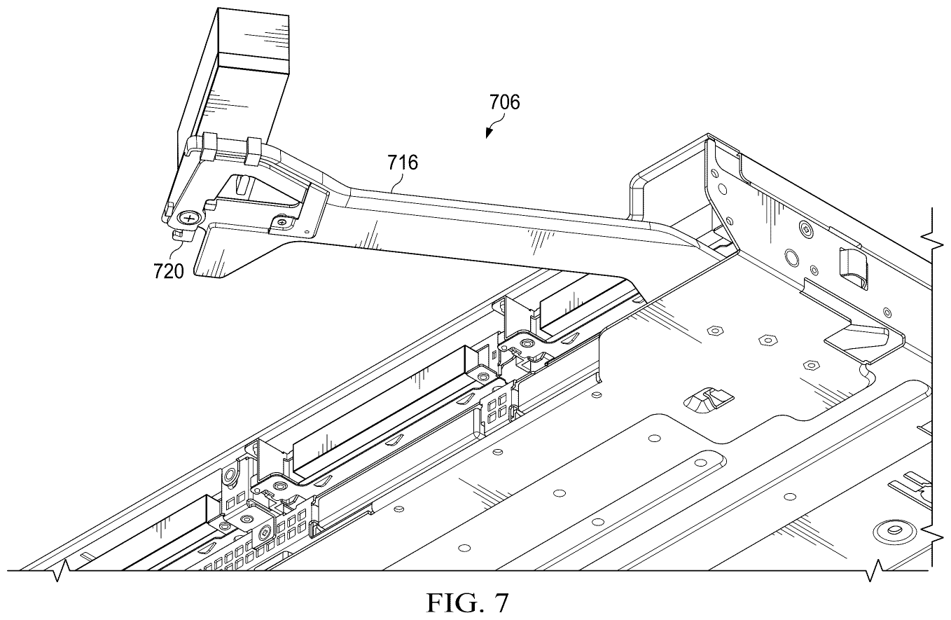

In certain embodiments, each cam lever 430, 432 includes a cam lever housing portion 440, a cam lever extended portion 442, a cam lever lock (see e.g., FIG. 7), a cam lever pivot portion 446, or a combination thereof. In certain embodiments, the cam lever extended portion 442 is positioned along an inside portion of the cam lever. In certain embodiments, the cam lever lock is positioned on the cam level extended portion 442. In certain embodiments, the cam lever pivot portion is positioned along an outside portion of the cam lever 430, 432. In certain embodiments, each cam lever 430, 432 is configured as mirror images of the other. In certain embodiments, a rack ejection device 420, 422 is attached to each of the pair of cam levers 430, 432. In certain embodiments, a rack ejection device 420, 422 is attached to a respective cam lever extended portion 442. In certain embodiments, the server information handling system conforms to the ORv3 server standard. In certain embodiments, the cam levers 430, 432 conform to the Orv3 server standard.

In certain embodiments, each rack ejection device 420, 422 performs a lock release operation. In certain embodiments, each rack ejection device 420, 422 generates a mechanical pinching action. In certain embodiments, the lock release operation includes the mechanical pinching action. In certain embodiments, the mechanical pinching action triggers a lock release of the cam lever 430. In certain embodiments, triggering the lock release of the cam lever, generates a spring force which causes the pressurized coolant quick disconnects to naturally push the server information handling system forward and clear of the liquid and power connections thereby rending the server safely disabled. In certain embodiments, this forward movement is relatively small (e.g., about an inch or two forward).

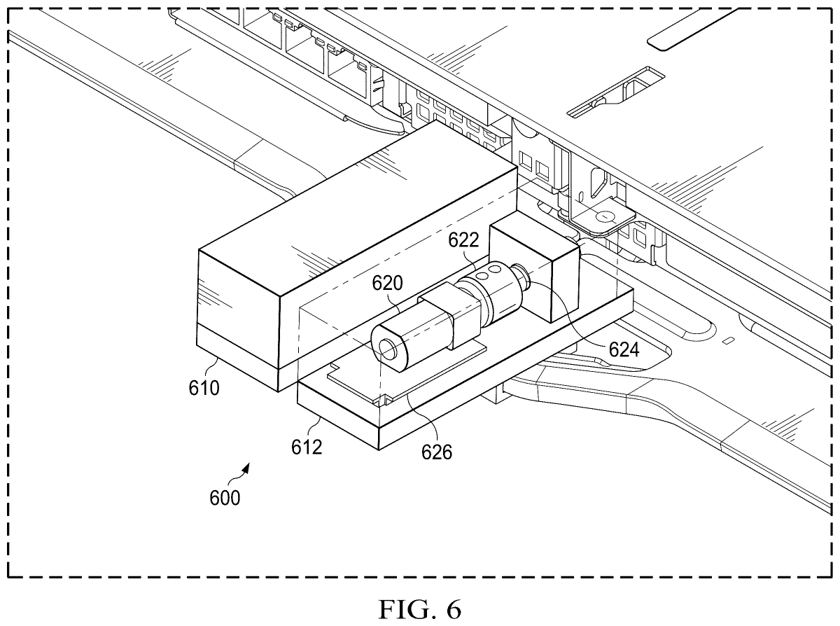

FIG. 6 shows a cut away perspective view of a server rack ejection system 600. In certain embodiments, the rack ejection system 600 corresponds to ejection system 150.

In certain embodiments, the rack ejection system 600 includes a rack ejection device 610. In certain embodiments, the rack ejection system 600 includes a pair of rack ejection devices 610, 612.

In certain embodiments, each rack ejection device 610, 612 includes a motor 620, a gear assembly 622, a finger component 624, a control and communication portion 626, or a combination thereof. In certain embodiments, the motor 622 and the gear assembly 622 drives the finger component 624. In certain embodiments, the finger component 624 trips the release mechanism of a cam handle of the cam. In certain embodiments, the control and communication portion 626 enables the ejection device to be controlled remotely. In certain embodiments, each rack ejection device 620, 622 is controlled remotely via respective control and communication portions 626.

FIG. 7 shows a front perspective view of a rack ejection system 700 in a disengaged orientation. In certain embodiments, the rack ejection system 700 corresponds to ejection system 150.

In certain embodiments, after the rack ejection system 700 releases the lock mechanism 720 of the cam 710 (thereby performing an eject event), the cam 710 pivots to a disengaged orientation. In certain embodiments, the finger component of the rack ejection system manipulates the cam lock mechanism 720 to disengage the cam from the chassis of the server information handling system and the cam swings out as a result. In certain embodiments, triggering the cam lock mechanism 720 of the cam lever generates a spring force which causes the pressurized coolant quick disconnects to naturally push the server information handling system forward and clear of the liquid and power connections thereby rending the server safely disabled. Once the cams arms are disengaged, the fluid pressure pushes the server forward resulting in a substantially simultaneous full disconnect from liquid cooling and power. In certain embodiments, the forward movement is generated by the fluid pressure associated with disengaging the liquid connections. In certain embodiments, this forward movement is relatively small (e.g., about an inch or two forward).

Note while the ejection system 700 is shown with a single ejection device, the ejection system 700 is often deployed with a pair of ejection devices, each associated with a respective cam arm. In certain embodiments, the pair of ejection devices are actuated as a set to release the server information handling system from the server rack.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A rack ejection system of a server type information handling system, comprising:
a cam lever, the cam lever including a cam lever lock mechanism, the cam lock mechanism being configured to engage the cam lever with a chassis of the information handling system; and,
an ejection device mounted on the cam lever, the ejection system being configured to manipulate the cam lever lock mechanism of the cam lever, manipulating the cam lever lock mechanism disengaging the cam lever from the chassis of the information handling system.

2. The rack ejection system of claim 1, wherein:
the cam lever and the ejection device correspond to a first cam lever and a first ejection device; and the rack ejection system further comprises:
a second cam lever, the second cam lever including a second cam lever lock mechanism, the second cam lock mechanism being configured to engage the second cam lever with the chassis of the information handling system; and,
a second ejection device mounted on the second cam lever, the second ejection system being configured to manipulate the second cam lever lock mechanism of the cam lever, manipulating the second cam lever lock mechanism disengaging the second cam lever from the chassis of the information handling system.

3. The rack ejection system of claim 2, wherein:
the first ejection device and the second ejection device are positioned towards a center portion of the server type information handling system.

4. The rack ejection system of claim 3, wherein:
the first ejection device and the second ejection device are positioned next to each other towards the center portion of the server type information handling system.

5. The rack ejection system of claim 1, wherein:
the ejection device includes a motor, a gear assembly and a finger component, the finger component being coupled to the cam lever lock mechanism; and,
the motor and the gear assembly generate a torque force, the torque force being applied to the finger component to cause the cam lever lock mechanism to disengage the cam lever from the chassis of the information handling system.

6. The rack ejection system of claim 5, wherein:
the ejection device further includes a control and communication portion, the control and communication portion enabling the ejection device to be controlled remotely.

7. A server type information handling system comprising:
an information handling system chassis; and,
rack ejection system coupled to the information handling system chassis, the rack ejection system comprising:
a cam lever, the cam lever including a cam lever lock mechanism, the cam lock mechanism being configured to engage the cam lever with the information handling system chassis; and,
an ejection device mounted on the cam lever, the ejection system being configured to manipulate the cam lever lock mechanism of the cam lever, manipulating the cam lever lock mechanism disengaging the cam lever from the the information handling system chassis.

8. The server type information handling system of claim 7, wherein:
the cam lever and the ejection device correspond to a first cam lever and a first ejection device; and the rack ejection system further comprises:
a second cam lever, the second cam lever including a second cam lever lock mechanism, the second cam lock mechanism being configured to engage the second cam lever with the chassis of the information handling system; and,
a second ejection device mounted on the second cam lever, the second ejection system being configured to manipulate the second cam lever lock mechanism of the cam lever, manipulating the second cam lever lock mechanism disengaging the second cam lever from the chassis of the information handling system.

9. The server type information handling system of claim 8, wherein:
the first ejection device and the second ejection device are positioned towards a center portion of the server type information handling system.

10. The server type information handling system of claim 9, wherein:
the first ejection device and the second ejection device are positioned next to each other towards the center portion of the server type information handling system.

11. The server type information handling system of claim 7, wherein:
the ejection device includes a motor, a gear assembly and a finger component, the finger component being coupled to the cam lever lock mechanism; and,
the motor and the gear assembly generate a torque force, the torque force being applied to the finger component to cause the cam lever lock mechanism to disengage the cam lever from the chassis of the information handling system.

12. The server type information handling system of claim 11, wherein:
the ejection device further includes a control and communication portion, the control and communication portion enabling the ejection device to be controlled remotely.

13. A system comprising:
a server rack; and,
an information handling system mounted to the server rack, the information handing system comprising:
an information handling system chassis; and,
a rack ejection system coupled to the information handling system chassis, the rack ejection system comprising:
a cam lever, the cam lever including a cam lever lock mechanism, the cam lock mechanism being configured to engage the cam lever with the information handling system chassis; and,
an ejection device mounted on the cam lever, the ejection system being configured to manipulate the cam lever lock mechanism of the cam lever, manipulating the cam lever lock mechanism disengaging the cam lever from the information handling system chassis.

14. The system of claim 13, wherein:
the cam lever and the ejection device correspond to a first cam lever and a first ejection device; and the rack ejection system further comprises:
a second cam lever, the second cam lever including a second cam lever lock mechanism, the second cam lock mechanism being configured to engage the second cam lever with the chassis of the information handling system; and,
a second ejection device mounted on the second cam lever, the second ejection system being configured to manipulate the second cam lever lock mechanism of the cam lever, manipulating the second cam lever lock mechanism disengaging the second cam lever from the chassis of the information handling system.

15. The system of claim 14, wherein:
the first ejection device and the second ejection device are positioned towards a center portion of the server type information handling system.

16. The system of claim 15, wherein:
the first ejection device and the second ejection device are positioned next to each other towards the center portion of the server type information handling system.

17. The system of claim 13, further comprising:
the ejection device includes a motor, a gear assembly and a finger component, the finger component being coupled to the cam lever lock mechanism; and,
the motor and the gear assembly generate a torque force, the torque force being applied to the finger component to cause the cam lever lock mechanism to disengage the cam lever from the chassis of the information handling system.

18. The system of claim 17, wherein:
the ejection device further includes a control and communication portion, the control and communication portion enabling the ejection device to be controlled remotely.
